(19) United States
(12) Patent Application Publication
(10) Pub. No.: US 2008/0105825 A1
(43) Pub. Date: May 8, 2008

(54) Laser scanning apparatus and method using diffractive optical elements

(76) Inventor: Taejoon Han, Sam Ramon, CA (US)

Correspondence Address: Raj Abhyanker, LLP;c/o Intellevate, P.O. Box 52050, Minneapolis, MN, 55402, US

(21) Appl. No.: 11/644,768

(22) Filed: Dec. 21, 2006

Related U.S. Application Data
(60) Provisional application No. 60/857,920, filed on Nov. 8, 2006.

(51) Int. Cl. G21K 5/04; H01L 21/428

(52) U.S. Cl. 250/393; 250/491.1; 438/479; 438/535; 257/E21.475

(57) ABSTRACT

Laser scanning apparatus and method using diffractive optical elements are disclosed. In one embodiment, an apparatus includes a radiation source to generate a radiation beam with an intensity profile and a wavelength capable of heating a region of a substrate, a beam shaping device based on a diffractive optical element (DOE) to transform the radiation beam to a particular shape with a particular intensity profile to illuminate the region and a state adapted to support the substrate. In another aspect, a method includes generating from a radiation source a radiation beam with an intensity profile and a wavelength capable of heating a region of a substrate transforming a shape of the radiation beam with the intensity profile to a particular shape of the radiation beam with a particular intensity profile through processing the radiation beam in a beam shaping device based on a diffractive optical element (DOE).

### CLAIMS OF PRIORITY

This patent application claims priority from U.S. provisional patent application No. 60/857,920, titled “laser scanning apparatus and method using diffractive optical elements” filed on Nov. 8, 2006.

### FIELD OF TECHNOLOGY

This disclosure relates generally to the technical fields of software and/or hardware technology and, in one example embodiment, to a laser scanning apparatus and method using diffractive optical elements.

### BACKGROUND

A laser thermal processing (LTP) (e.g., which may take advantage of an extremely accurate and/or small scale laser) may be used to improve a control of a dopant diffusion and/or activation during a manufacture of a semiconductor (e.g., in a microscopic scale) device. A silicon used in the semiconductor device may be doped with impurities (e.g., a boron and an arsenic) to increase a conductivity of the semiconductor device. A thin film of a doped material of the semiconductor device may also become thinner, thus requiring that the doped material to contain a higher concentration of dopant atoms (e.g., the impurities such as the boron and the arsenic) to maintain an electrical conductivity and/or a greater precision in a dopant concentration.

A process of implanting the impurities may damage a silicon crystal of the semiconductor device. To anneal (e.g., heal) a damage of the silicon crystal, the semiconductor device may be heated very rapidly to a melting point and/or then quickly cooled. The LTP may take advantage of a microsecond and/or a nanosecond pulsed laser and continuous wave laser to repair the damage (e.g., an implantation damage) in a fraction of a second and/or thus improve a quality of a final structure of the silicon crystal.

The LTP may use a laser source and/or a multiple mirrors (e.g., refractive and/or reflective) to perform the annealing. The laser source may need to generate a large power output (e.g., 3 KW through 10 KW) to raise a temperature (e.g., between 1300° C. and 1500° C.) required for the annealing of a doped material. A need for the large power output may add to a cost of a LTP equipment.

The multiple mirrors (e.g., as well as an aperture) may be required to create a shape (e.g., a line shape) of a laser radiation beam touching the doped material of the semiconductor device to perform the annealing. To create the shape, the number of mirrors may be spaced apart (e.g., 3 meters in total) to relay the radiation beam (e.g., through a reflection and/or a refraction). A distance between the laser source and the doped material may result in a loss in power (e.g., 90% of a power of the laser source may be lost), thus requiring the laser source to have the large output. Also, the LTP process depending on the multiple mirrors and the aperture to create the shape of the radiation beam may be difficult to create other shapes.

Furthermore, the usage of the multiple mirrors may delay a scanning process of a wafer being used to manufacture the semiconductor device. In addition, the usage of the multiple mirrors may require a lengthy preparation time to calibrate multiple mirrors when an error is detected and/or an adjustment in the shape of the radiation beam is needed. Accordingly, a slow act to adjust the error (e.g., due to an inaccurate set-up of the multiple mirrors) may result in a poor yield (e.g., a percentage of chips in a finished wafer that pass all test and/or functions properly) of the semiconductor device.

### SUMMARY

Laser scanning apparatus and a method using diffractive optical elements is disclosed. In one aspect, an apparatus includes a radiation source (e.g., the radiation source may be a solid state laser, a diode laser, a gas laser, and/or a metal vapor laser of continuous oscillation and/or pulse oscillation with a power between 100 Watts and 3 kWatts) to generate a radiation beam with an intensity profile and a wavelength (e.g., the wavelength may be 10.6 um for a CO2 laser, 0.4 um˜0.9 um for a diode laser, and/or 0.157 um for a F2 laser) capable of heating a region of a substrate, a beam shaping device based on a diffractive optical element (DOE) (e.g., the DOE may be a reflective DOE and/or a transmissive DOE) to transform the radiation beam to a particular shape (e.g., the particular shape may be a line and a rectangle) with a particular intensity profile (e.g., the particular intensity profile may be a fang shape which has a higher energy distribution of the radiation beam towards each side of the particular shape) to illuminate the region, and a stage adapted to support the substrate, wherein the beam shaping device and the stage may be relatively moved to illuminate the particular shape with the particular intensity profile of the radiation beam to the region.

In addition, the DOE may be a multilayer diffractive optical element (DOE) which may include a 16 level, a 64 level, and/or a 256 level of diffractive layers. Furthermore, a maximum distance of the radiation beam traveled between the radiation source and the region of the substrate may be less than 80 cm. Also, the apparatus may include a reflectivity measurement device to measure the intensity profile of the radiation beam illuminating the region through sampling the radiation beam reflected from the region. The apparatus may further include a optical element to relay the radiation beam between the radiation source and the substrate.

Moreover, the apparatus may include a projection apparatus between the DOE and the substrate to focus the radiation beam to the region of the substrate. The apparatus may also include a beam detector device to measure the intensity profile and/or the wavelength of the radiation beam fed into the DOE through capturing a sample of the radiation beam using a DOE based mirror and/or a mirror with a beam sampler (e.g., a beam splitter). In addition, a method may also include a cooling device coupled to an unused side of the DOE to control a temperature of the DOE.

In another aspect, a method includes generating from a radiation source a radiation beam with an intensity profile and a wavelength capable of heating a region of a substrate and transforming a shape of the radiation beam with the intensity profile to a particular shape (e.g., the particular shape may be based on a combination of lines (e.g., the combination of lines may take a cross shape with a main beam surrounded by a pre beam, two side beams, and/or a post beam with a temperature of the main beam may be at least 1300° C. and a temperature of the pre beam, the two side beams, and/or the post beam may be between 400° C. and 600° C.) formed by the radiation beam with each of the lines to have an intensity profile of a fang shape) of the radiation beam with a particular intensity profile through processing the radiation beam in a beam shaping device based on a diffractive optical element (DOE).

Furthermore, the method includes illuminating the region of the substrate with the particular shape of the radiation beam with the particular intensity profile while the radiation beam and the substrate are relatively moved. The method may further include illuminating different layers of the region of the substrate through generating multiple radiation beams using a plurality of radiation sources and a plurality of beam shaping devices, wherein each of the multiple radiation beams to have a unique wavelength.

Also, the method may include generating a first radiation beam of the multiple radiation beams with its wavelength ranging between a wavelength of a visible light and a wavelength of an infrared light to illuminate at least one of a silicon substrate and a poly-silicon substrate, and generating a second radiation beam of the multiple radiation beams with its wavelength ranging between a wavelength of a ultraviolet light and a wavelength of an extreme ultraviolet light to illuminate dielectric layers.

In addition, the method may include continuously illuminating the region of the substrate with the combination of lines. Moreover, the method may include periodically illuminating the region of the substrate with a number of parallel lines (e.g., the number of parallel lines may be pulse-based multiple rectangular beams with the intensity profile of each of the pulse-based multiple rectangular beams is the fang-shape).

In yet another aspect, a method includes forming a semiconductor film over a substrate, adding an impurity element to the semiconductor film, illuminating a radiation beam of a radiation source processed through a beam shaping device based on a diffractive optical element (DOE) to activate the impurity element and performing crystallizing the semiconductor film, driving the impurity element to a target depth of the substrate, and/or converting the impurity element to a chemically stable form.

In another alternative aspect, a method includes forming at least one dielectric film to a substrate and illuminating a radiation beam of a radiation source processed through a beam shaping device based on a diffractive optical element (DOE) to apply a stress to the at least one dielectric film.

The methods, systems, and apparatuses disclose herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a system view of a laser scanner, according to one embodiment.

FIG. 2 is a schematic diagram of the laser scanner of FIG. 1, according to one embodiment.

FIG. 3A is a schematic diagram of the laser scanner of FIG. 1 having a reflective DOE, according to one embodiment.

FIG. 3B is a schematic diagram of the laser scanner of FIG. 1 having a transmissive DOE, according to one embodiment.

FIG. 4A is a schematic diagram of a laser scanning device using a single DOE and multiple mirrors, according to one embodiment.

FIG. 4B is a schematic diagrammatic view of a laser scanning device using multiple DOEs and multiple mirrors, according to one embodiment.

FIG. 5 is image views of various shapes of the radiation beam, according to one embodiment.

FIG. 6 is a top view and an intensity profile of a combination of lines formed by the radiation beam, according to one embodiment.

FIG. 7 is a top view and an intensity profile of with a number of parallel lines formed by the radiation source, according to one embodiment.

FIG. 8A is a schematic diagram of the laser scanner of FIG. 1 with two laser sources generating two radiation beams having two different wavelengths (λ), according to one embodiment.

FIG. 8B is a view of multiple layers of a wafer targeted by the laser scanner of FIG. 8A, according to one embodiment.

FIG. 9 is a schematic diagram of the laser scanner of FIG. 1 with multiple laser sources generating multiple radiation beams with a unique wavelength, according to one embodiment.

FIG. 10 is a schematic diagram of a detector monitoring the radiation beam using a DOE based mirror and/or a mirror with a beam sampler, according to one embodiment.

FIG. 11 is the process flow of generating from a radiation source a radiation beam with an intensity profile and a wavelength capable of heating a region of a substrate, according to one embodiment.

FIG. 12 is a process flow of forming a semiconductor over a substrate, according to on embodiment.

Other features of the present embodiments will be apparent from the accompanying drawings and from the detailed description that follows.

### DETAILED DESCRIPTION

Laser scanning apparatus and method using diffractive optical elements are disclosed. In the following description, for purposes of explanation, numerous specific details are set forth in order to provide a thorough understanding of the various embodiments. It will be evident, however, to one skilled in the art that the various embodiments may be practiced without these specific details.

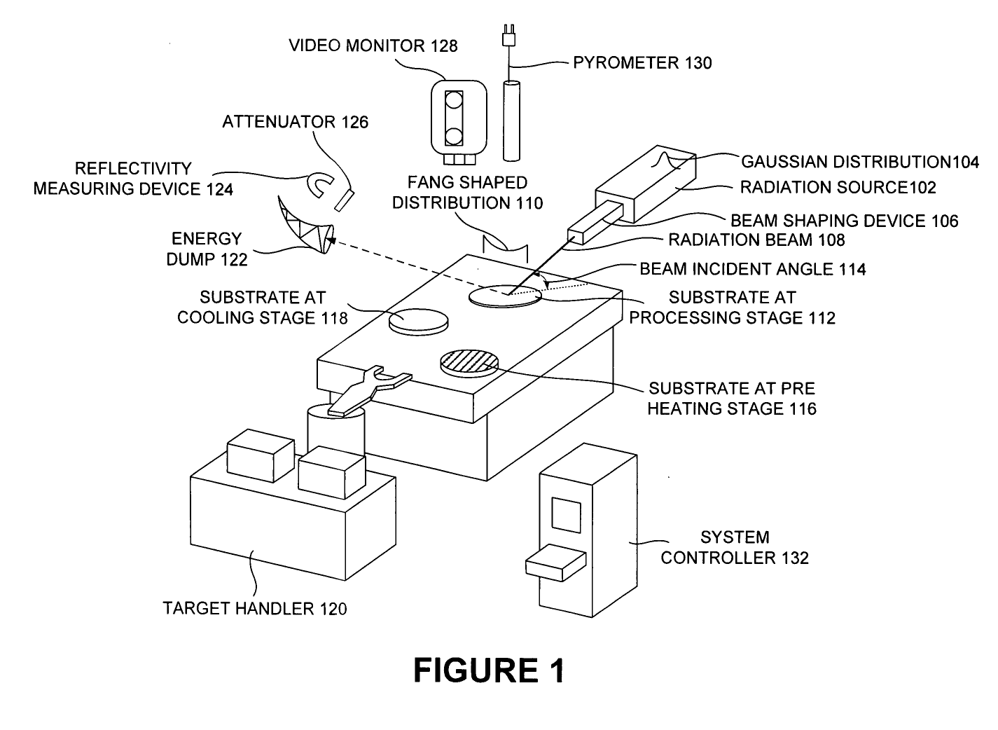

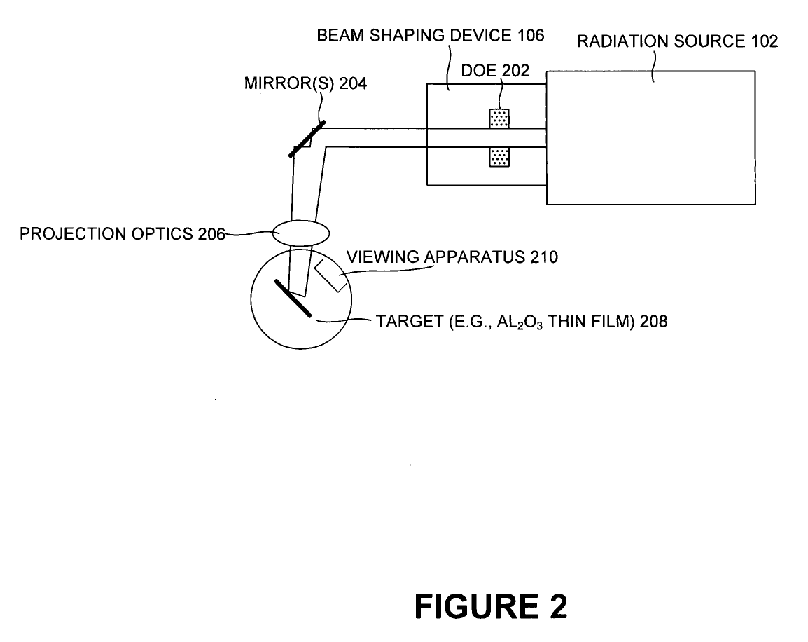

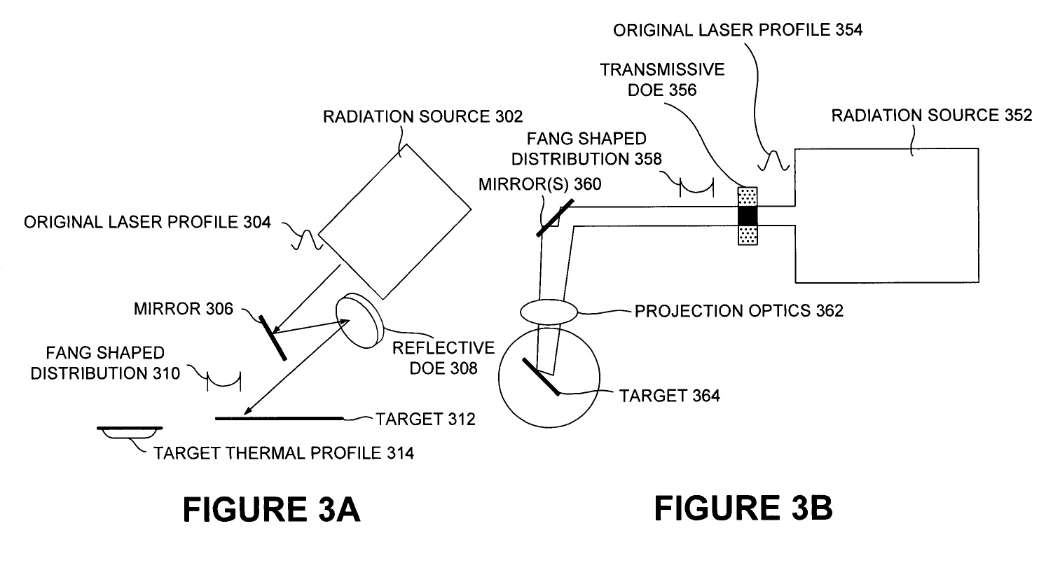

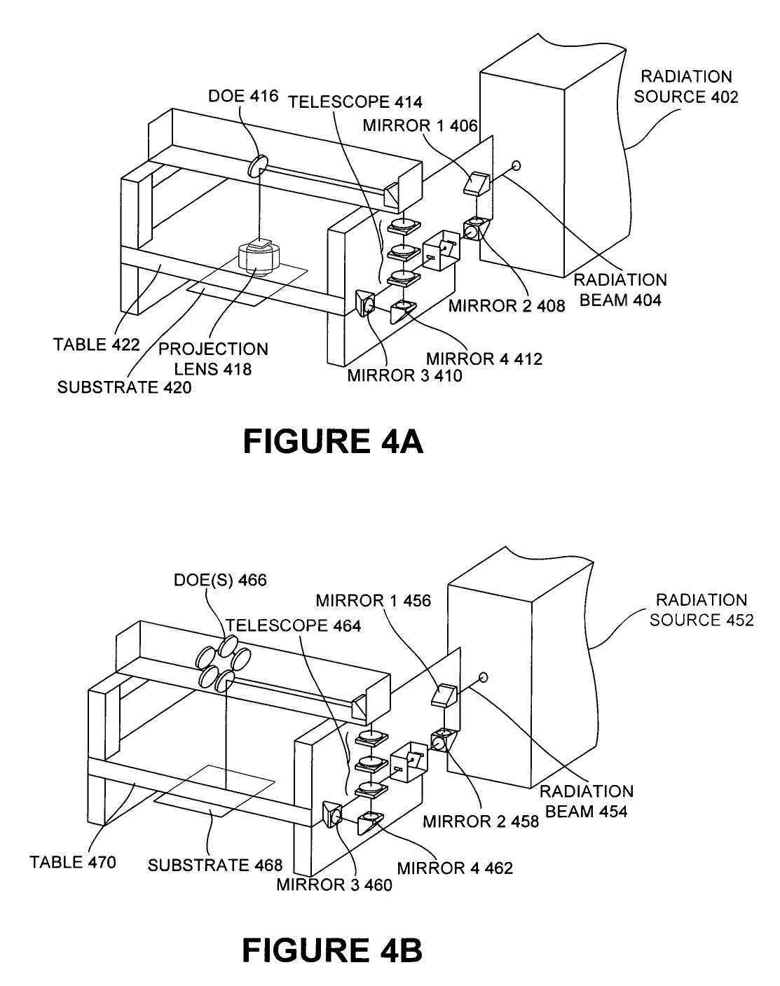

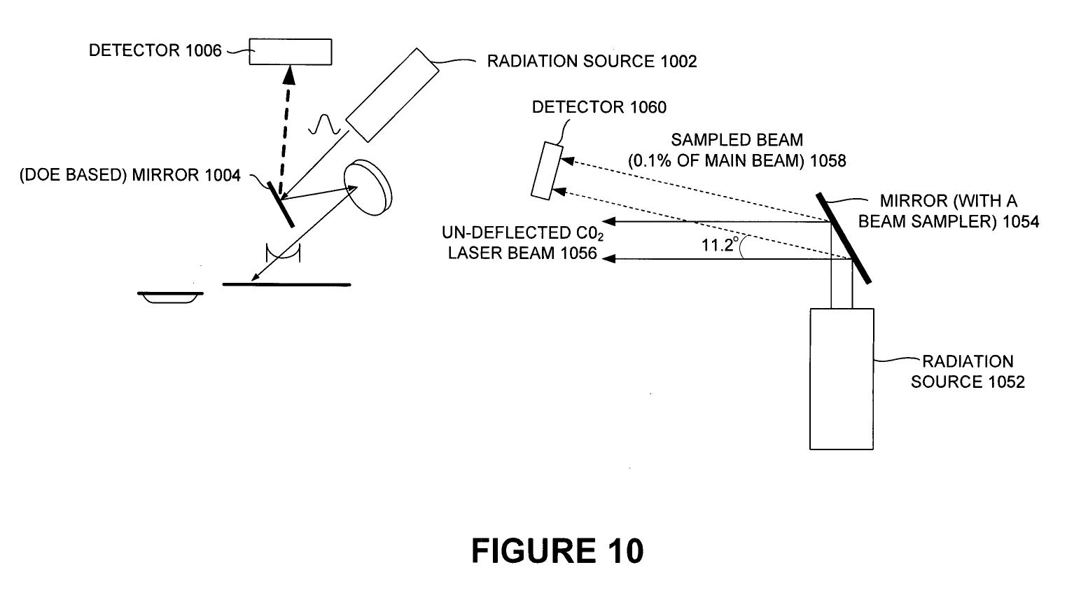

In one embodiment, an apparatus includes a radiation source (e.g., the radiation source 102 of FIG. 1 and 2, the radiation source 302 and the radiation source 352 of FIG. 3, the radiation source 402 of FIG. 4 and the radiation source 1002 and the radiation source 1052 of FIG. 10) to generate a radiation beam (e.g., the radiation beam 108 of FIG. 1) with an intensity profile and a wavelength capable of heating a region of a substrate, a beam shaping device (e.g., the beam shaping device 106 of FIGS. 1 and 2) based on a diffractive optical element (DOE) (e.g., the DOE 202 of FIG. 2) to transform the radiation beam (e.g., the radiation beam 108 of FIG. 1 and the radiation beam 404 of FIG. 4) to a particular shape with a particular intensity profile to illuminate the region and a stage adapted to support the substrate (e.g., the substrate 420 of FIG. 4), wherein the beam shaping device (e.g., the beam shaping device 106 of FIGS. 1 and 2) and the stage are relatively moved to illuminate the particular shape with the particular intensity profile of the radiation beam (e.g., the radiation beam 108 of FIG. 1) to the region.

In another embodiment, a method includes generating from a radiation source (e.g., the radiation source 102 of FIGS. 1 and 2, the radiation source 302 and the radiation source 352 of FIG. 3, the radiation source 402 of FIG. 4 and the radiation source 1002 and the radiation source 1052 of FIG. 10) a radiation beam (e.g., the radiation beam 108 of FIG. 1) with an intensity profile and a wavelength capable of heating a region of a substrate (e.g., the substrate 420 of FIG. 4), transforming a shape of the radiation beam (e.g., the radiation beam 108 of FIG. 1 and the radiation beam 404 of FIG. 4A and the radiation beam 454 of FIG. 4B) with the intensity profile to a particular shape of the radiation beam (e.g., the radiation beam 108 of FIG. 1 and the radiation beam 404 of FIG. 4A and the radiation beam 454 of FIG. 4B) with a particular intensity profile through processing the radiation beam (e.g., the radiation beam 108 of FIG. 1 and the radiation beam 404 of FIG. 4A and the radiation beam 454 of FIG. 4B) in a beam shaping device (e.g., the beam shaping device 106 of FIGS. 1 and 2) based on a diffractive optical element (DOE) (e.g., the DOE 202 of FIG. 2) and illuminating the region of the substrate (e.g., the substrate 428 and the substrate 468 of FIGS. 4A and 4B) with the particular shape of the radiation beam (e.g., the radiation beam 108 of FIG. 1 and the radiation beam 404 of FIG. 4A and the radiation beam 454 of FIG. 4B) with the particular intensity profile while the radiation beam and the substrate are relatively moved.

In yet another embodiment, a method includes forming a semiconductor film over a substrate (e.g., the substrate 428 and the substrate 468 of FIGS. 4A and 4B), adding an impurity element to the semiconductor film, illuminating a radiation beam (e.g., the radiation beam 108 of FIG. 1 and the radiation beam 404 of FIG. 4A and the radiation beam 454 of FIG. 4B) of a radiation source (e.g., the radiation source 102 of FIGS. 1 and 2, the radiation source 302 and the radiation source 352 of FIG. 3, the radiation source 402 of FIG. 4 and the radiation source 1002 and the radiation source 1052 of FIG. 10) processed through a beam shaping device (e.g., the beam shaping device 106 of FIGS. 1 and 2) based on a diffractive optical element (DOE) (e.g., the DOE 202 of FIG. 2) to activate the impurity element and performing crystallizing the semiconductor film, driving the impurity element to a target depth of the substrate, and/or converting the impurity element to a chemically stable form.

In another alternative embodiment, a method includes forming at least one dielectric film to a substrate (e.g., the substrate 428 and the substrate 468 of FIGS. 4A and 4B) and illuminating a radiation beam (e.g., the radiation beam 108 of FIG. 1 and the radiation beam 404 of FIG. 4A and the radiation beam 454 of FIG. 4B) of a radiation source (e.g., the radiation source 102 of FIGS. 1 and 2, etc.) Processed through a beam shaping device (e.g., the beam shaping device 106 of FIGS. 1 and 2) based on a diffractive optical element (DOE) (e.g., the DOE 202 of FIG. 2) to apply a stress to the at least one dielectric film.

FIG. 1 is a system view of a laser scanner, according to one embodiment. Particularly FIG. 1 illustrates a radiation source 102, a Gaussian distribution 104, a beam shaping device 106, a radiation beam 108, a fang shaped distribution 110, a substrate at processing stage 112, a beam incident angle 114, a substrate at pre heating stage 116, a substrate at cooling stage 118, a target handler 120, an energy dump 122, a reflectivity measuring device 124, a video monitor 128, a pyrometer 130, a system controller 132, according to one embodiment.

The radiation source 102 may generate a radiation beam with an intensity profile and a wavelength capable of heating a region of a substrate. The Gaussian distribution 104 may be a probability distribution of the same general form, differing in their location and scale parameters the mean (e.g., average) and/or standard deviation (e.g., variability) of the radiation source. The beam shaping device 106 may be a device used to transform the radiation beam to a particular shape (e.g., an elliptic beam to a circular beam) with a particular intensity profile to illuminate the region of the substrate at processing stage. The radiation beam 108 may be the energy (e.g., a solid state laser, diode laser, a gas laser, and a metal vapor laser) emitted in the form of waves or particles from the radiation source to a substrate at processing stage 112.

The fang shaped distribution 110 may have a higher energy distribution of the radiation beam towards each side of the particular shape. The substrate at processing stage 112 may be a substrate disposed on a support platform for process where the radiation beam of a wavelength may strike to heat the substrate. The beam incident angle 114 may be the angle between radiation beams with respect to detectors, monitors depending on design/configuration and/or may maximize absorbance to the target.

The substrate at pre heating stage 116 may be a substrate disposed on a support platform for preheating the substrate. The substrate at cooling stage 118 may be a substrate disposed on a support platform for cooling the substrate. The target handler 120 may handle the substrate (e.g., wafer/FAD board) and/or relatively move the substrate. The energy dump 122 may absorbs laser energy emitted in the process while a beam may be tuned for a specific application. The reflectivity measuring device 124 may measure the intensity profile of the radiation beam illuminating the region through sampling the radiation beam reflected from the region.

The attenuator 126 may be an electronic device that reduces amplitude or power of a signal without appreciably distorting its waveform and/or a degree of attenuation may be fixed, continuously adjustable and/or incrementally adjustable. The video monitor 128 may be a video generating device displaying result related to the laser scanning. The pyrometer 130 may be a temperature measuring device, which may consist of several different arrangements measuring the temperature of the heat produced by the radiation beam 106.

The system controller 132 may be a self-contained hardware and/or software component handling a specific task of controlling (e.g., calibrating) the laser scanner through communicating a set of commands based on control data. The radiation source 102 may generate a radiation beam with an intensity profile and a wavelength in Gaussian distribution 104 form. The radiation beam 108 may be transformed to a particular shape by the beam shaping device that may be coupled with the radiation source 102.

The radiation beam 108 may strike the substrate at processing stage 112 with certain angle (e.g., the beam incident angle 114), thus increasing the temperature of the substrate and/or the reflectivity measuring device 124 may measure the intensity profile of the radiation beam. The target handler 120 may handle the substrate at cooling stage 118 and substrate at pre heating stage 116. The laser energy emitted in the process may be absorbed by the energy dump 122. The entire process may be displayed on video monitor 128 and/or controlled by the system controller 132.

For example, an apparatus includes the radiation source 102 to generate the radiation beam 108 with an intensity profile and a wavelength capable of heating a region of a substrate (e.g., the substrate at processing stage). An apparatus also includes a beam shaping device based on a diffractive optical element (DOE) (e.g., the DOE 202 of FIG. 2) to transform the radiation beam 108 to a particular shape (e.g., fang shape, line shape, crater shape, top hat shape, etc.) With a particular intensity profile to illuminate the region (e.g., the region of the substrate).

In addition, an apparatus may include a stage adapted to support the substrate. Furthermore, the beam shaping device 106 and the stage may be relatively moved to illuminate the particular shape (e.g., fang shape, line shape, crater shape, top hat shape, etc.) With the particular intensity profile of the radiation beam 108 to the region. Moreover, a maximum distance of the radiation beam 108 traveled between the radiation source 102 and the region of the substrate may be less than 80 cm. The apparatus may further include the reflectivity measurement device 124 to measure the intensity profile of the radiation beam 108 illuminating the region through sampling the radiation beam 108 reflected from the region. In addition, the apparatus may also include an optical element to relay the radiation beam 108 between the radiation source 102 and the substrate.

Furthermore, the radiation beam 108 may be generated from the radiation source 102 with an intensity profile and a wavelength capable of heating a region of a substrate. Also, a shape of the radiation beam 108 with the intensity profile may be transformed to a particular shape of the radiation beam 108 with a particular intensity profile through processing the radiation beam 108 in the beam shaping device 106 based on a diffractive optical element (DOE) (e.g., the DOE 202 of FIG. 2).

In addition, the region of the substrate with the particular shape of the radiation beam 108 with the particular intensity profile may be illuminated while the radiation beam 108 and the substrate are relatively moved. Moreover, a semiconductor film may be formed over a substrate. Also, an impurity element may be added to the semiconductor film.

Furthermore, the radiation beam 108 of the radiation source 102 processed through the beam shaping device 106 based on the diffractive optical element (DOE) (e.g., the DOE 202 of FIG. 2) may be illuminated to activate the impurity element. In addition, the semiconductor film may be crystallized, the impurity element may be driven to a target depth of the substrate, and/or the impurity element may be converted to a chemically stable form.

In another example embodiment, dielectric films may be deposited over a substrate. Furthermore, the radiation beam 108 of the radiation source 102 processed through the beam shaping device 106 based on the diffractive optical element (DOE) (e.g., the DOE 202 of FIG. 2) may be illuminated to adjust a stress of the dielectric films (e.g., and/or inducing the stress in the process).

FIG. 2 is a schematic diagram of the laser scanner of FIG. 1, according to one embodiment. Particularly, FIG. 2 illustrates a radiation source 102, a beam shaping device 106, a DOE 202, a mirror(s) 204, projection optics 206, a target 208 and/or a viewing apparatus 210, according to one embodiment. The radiation source 102 may be a laser beam and/or radiation beam. The radiation source 102 may be a solid state laser, diode laser, a gas laser, and a metal vapor laser with one of continuous oscillation and/or pulse oscillation with a power between 100 Watts and 3 kWatts that may be operated on a certain wavelength (e.g., 10.6 um for a CO2 laser, 0.4 um˜0.9 um for a diode laser, and 0.157 um for a F2 laser).

Moreover, the laser beam may be needed on a surface of a wafer to carry annealing process (a heat treatment that alters the microstructure of a material causing changes in properties such as strength and hardness). The beam shaping device 106 may be a device used to shape the laser beam to a particular shape with a particular intensity profile that may be emitted through the DOE 202 from the radiation source (e.g., the radiation source 102 of FIG. 1) to illuminated a region of the substrate.

The DOE (e.g., diffractive optical element) 202 may be a multilayer (e.g., a 16 level, a 64 level, and a 256 level of diffractive layers) device designed to generate a laser intensity distribution emitted from the radiation source 102 that may not be achieved using a conventional lens (e.g., a thin optical lens that may consist of concentric rings used primarily in spotlights, overhead projectors, etc.) and/or mirrors. Advanced MEMS and/or semiconductor device manufacturing technology (e.g., sub-micron design rules) combined with a flexibility of the DOE 202 in a design of beam shapes may be utilized to obtain an accuracy and/or a repeatability of the DOE 202, thus enabling a laser scanning device based on the DOE 202 to anneal and/or thermal process a region (e.g., of less than 100 s microns in thickness) with a desired uniformity and/or a minute control.

The beam of the DOE (e.g., an adoption of the DOE 202 may reduce a number of other optical components, such as lenses and mirrors in a laser scanning device) may be transformed into novel shapes (e.g., a line shape, a concave shape, etc.). The mirror(s) 204 may be used to reflect the light from the laser beam to a specified amount. The mirror(s) 204 may diffract (e.g., bend the light objects) the beam emitted by the radiation source (e.g., the radiation source 102 of FIG. 1). The mirror(s) 204 may be diffractive, deflective, reflective, and/or transmissive in a variety of shapes (e.g., cone, cylinder, etc.). The projection optics 206 may be used to project the laser beam on a surface that may be reflected from the mirror(s) 204.

The target 208 may be a substrate (e.g., a base layer that may have several other layers deposited on it e.g., Al₂O₃ thin film). The viewing apparatus 210 may be a single element (e.g., a lens and/or a mirror) and/or made of multiple elements. The viewing apparatus 210 may be used to modify the radiation beam (e.g., the radiation beam 102 of FIG. 1) to downstream the target.

In example embodiment of FIG. 2, the radiation beam 108 generated by the radiation source 102 may be emitted through the DOE 202 that may shape the laser beam and/or change the intensity distribution by striking the mirror 204. The laser beam may then pass through the projection optics 206. The laser beam may reach the target 208 that may be viewed through the viewing apparatus 210.

For example, an apparatus may include a radiation source (e.g., the radiation source may be a solid state laser, a diode laser, a gas laser, and/or a metal vapor laser of continuous oscillation and pulse oscillation with a power between 100 Watts and 3 kWatts) to generate a radiation beam (e.g., the radiation beam 108 of FIG. 1) with an intensity profile and a wavelength (e.g., the wavelength may be 10.6 um for a CO2 laser, 0.4 um˜0.9 um for a diode laser, and/or 0.157 um for a F2 laser) capable of heating a region of a substrate.

The apparatus may also include the beam shaping device 106 based on the diffractive optical element (DOE) 202 (e.g., the DOE 202 may be a multilayer diffractive optical element (DOE) which may include a 16 level, a 64 level, and/or a 256 level of diffractive layers) to transform the radiation beam (e.g., the radiation beam 108 of FIG. 1) to a particular shape (e.g., the fang shape, the line shape, the crater shape, etc.) With a particular intensity profile to illuminate the region. Furthermore, the apparatus may include an optical element to relay the radiation beam (e.g., the radiation beam 108 of FIG. 1) between the radiation source 102 and the substrate.

The apparatus may also include a projection apparatus (e.g., the projection optics 362 of FIG. 3 and the projection lens 418 of FIG. 4A) between the DOE 202 and the substrate to focus the radiation beam 108 to the region of the substrate. In addition, the apparatus may also include a cooling device coupled to an unused side of the DOE to control a temperature of the DOE. The cooling device may be effective in brining down a temperature the reflective DOE 308 due to a high power laser emanating from the radiation source 302 of FIG. 3.

FIG. 3A is a schematic diagram of the laser scanner of FIG. 1 having a reflective DOE, according to one embodiment. Particularly, FIG. 3A illustrates a radiation source 302, original laser profile 304, mirror 306, reflective DOE 308, fang shaped distribution 310, target 312, and/or target thermal profile 314, according to one embodiment.

The radiation source 302 may emit a radiation beam (e.g., a laser source) with one of continuous oscillation and/or pulse oscillation with a power (e.g., between 100 Watts and 3 KWatts) that may be operated on a certain wavelength (e.g., 10.6 um for a CO2 laser, 0.4 um˜0.9 um for a diode laser, and 0.157 um for a F2 laser). The original laser profile 304 may be a profile of a laser beam that may be originated from the radiated source 302. The mirror 306 may diffract (e.g., to bend) the beam emitted by the radiation source 302.

The radiation beam may be reflected and/or deflected by the mirror towards the reflective DOE 308. The reflective DOE 308 may process the radiation beam 302 to modify a shape and/or an intensity of the radiation beam 302. The radiation beam may be modified and/or reached by the reflective DOE and may be reach the target 312. The fang shaped distribution 310 of the radiation beam may take an upward concave shape that may increase the intensity of the radiation beam towards both edges (e.g., sides) of the fang shaped distribution. The target 312 may receive the laser beam that may be reflected from the mirror 306 through the reflective DOE 308. The target thermal profile 314 may be the profile that may keep graphical records of temperatures at a specific location.

In example embodiment of FIG. 3A, the radiation beam generated by the radiation source 302 may have an original laser profile that may change the direction and/or intensity distribution by striking the mirror(s) 306. The laser beam may then strike the reflective DOE 308 that may shape the beam that may produce a fang shaped distribution 310. The beam may reach the target 312 that may provide the target thermal profile 314.

For example, an apparatus includes the radiation source 302 to generate the radiation beam (e.g., the radiation beam 108 of FIG. 1) with an intensity profile and a wavelength capable of heating a region of a substrate. Also, the DOE (e.g., the reflective DOE 308) may be a multilayer diffractive optical element (DOE) which may include a 16 level, a 64 level, and/or a 256 level of diffractive layers. In addition, the apparatus may include an optical element to relay the radiation beam (e.g., the radiation beam 108 of FIG. 3A) between the radiation source 302 and the substrate.

Moreover, the apparatus may include a projection apparatus between the DOE (e.g., the reflective DOE 308 of FIG. 3A) and the substrate to focus the radiation beam (e.g., the radiation beam 108 of FIG. 1) to the region of the substrate. The apparatus may also include a cooling device coupled to an unused side of the DOE (e.g., the reflective DOE 308 of FIG. 3A) to control a temperature of the DOE (e.g., the reflective DOE 308 of FIG. 3A).

FIG. 3B is a schematic diagram of the laser scanner of FIG. 1 having a transmissive DOE, according to one embodiment. Particularly, FIG. 3B illustrates a radiation source 352, original laser profile 354, a transmissive DOE 356, a fang shaped distribution 358, a mirror(s) 360, a projection optics 362, and/or a target, according to one embodiment.

The radiation source 352 may be a laser beam and/or radiation beam. The radiation source 352 may be a solid state laser, diode laser, a gas laser, and a metal vapor laser with one of continuous oscillation and/or pulse oscillation with a power between 100 Watts and 3 kWatts that may be operated on a certain wavelength (e.g., 10.6 um for a CO2 laser, 0.4 um˜0.9 um for a diode laser, and 0.157 um for a F2 laser). The original laser profile 354 may be a profile of a laser beam that may be originated from the radiated source 352. The transmissive DOE 356 may transmit the laser beam emitted by the radiation source 352.

The fang shaped distribution 310 of the radiation beam 302 may take an upward concave shape that may increase the intensity of the radiation beam 302 towards both edges (e.g., sides) of the fang shaped distribution after receiving the laser beam emitted from the transmission DOE. The mirror(s) 360 may diffract and/or reflect the laser beam emitted through the transmission DOE by the radiation source 352.

The projection optics 362 may be the optics used to project the laser beam on a surface of the target 364 that may be reflected from the mirror(s) 360. The projection optics 362 may also state the behavior of the laser beam. The target 364 may be a substrate (e.g., a base layer that may have several other layers deposited on it e.g., Al₂O₃ thin film). In example embodiment of FIG. 3B, the radiation beam emitted by the radiation source 352 may have the original laser profile 354 that may be passed through the transmissive DOE 356 and/or may change the direction and/or intensity distribution by striking the mirror(s) 360. The laser beam may pass through the projection optics 362 and/or reach the target 364.

For example, an apparatus includes the radiation source 352 to generate the radiation beam (e.g., the radiation beam 108 of FIG. 1) with an intensity profile and a wavelength capable of heating a region of a substrate. The apparatus may further include an optical element to relay the radiation beam (e.g., the radiation beam 108 of FIG. 1) between the radiation source 352 and the substrate (e.g., the target 364 of FIG. 3B).

Moreover, the apparatus may include a projection apparatus (e.g., the projection optics 362 of FIG. 3B) between the DOE (e.g., the transmissive DOE 356 of FIG. 3B) and the substrate to focus the radiation beam (e.g., the radiation beam 108 of FIG. 1) to the region of the substrate (e.g. the target 364 of FIG. 3). In addition, the apparatus may also include a cooling device coupled to an unused side of the DOE (e.g., the transmissive DOE 356 OF FIG. 3) to control a temperature of the DOE (e.g., the transmissive DOE 356 OF FIG. 3).

FIG. 4A is a schematic diagram of a laser scanning device using a single DOE and multiple mirrors, according to one embodiment. Particularly FIG. 4A illustrates a radiation source 402, a radiation beam 404, a mirror 1 406, a mirror 2 408, a mirror 3 410, a mirror 4 412, a telescope 414, a DOE 416, a projection lens 418, a substrate 420 and a table 422. The radiation source 402 may generate a radiation beam with an intensity profile and a wavelength capable of heating a region of a substrate. The radiation beam 404 may be the energy (e.g., a solid state laser, diode laser, a gas laser, and a metal vapor laser) emitted in the form of waves or particles from the radiation source to a substrate at processing stage.

The mirror(s) (e.g., the mirror 1 406, the mirror 2 408, the mirror 3 410, the mirror 412 of FIG. 4A) may be a diffractive, deflective, reflective, and/or transmissive in a variety of shapes (e.g., cone cylinder, concave, convex, etc.) used to change the direction of beam of light as a whole and/or may provide high reflectance and/or durability at individual laser wavelength ranges. The telescope 414 may work by employing one or more curved optical elements lenses or mirrors to gather light or other electromagnetic radiation and/or bring that light or radiation to a focus.

The DOE 416 may single DOE and may be a computer generated holographic device that may be used for laser beam shaping and/or sampling. The DOE 416 may be designed to generate a laser intensity distribution that may not be achieved using a conventional lenses and/or mirrors. The projection lens 418 may cause light to converge, concentrate and/or diverge accordingly modifying the beam projected from the DOE 416. The substrate 420 may be the base material (e.g., films, foils, textiles, fabrics, plastics, any variety of paper) onto which images may be printed. The table 422 may support the substrate 420 to be laser scanned.

In example embodiment in FIG. 4A, the radiation beam 404 generated by the radiation source 402 may change the direction and/or intensity distribution by striking the mirror(s) (e.g., the mirror 1 406, the mirror 2 408, the mirror 3 410, the mirror 412 of FIG. 4A) and/or by passing through the telescope 414. The laser beam may then strike the DOE 416 that may shape the beam. The beam may be modified by the projection lens 418 as a single DOE 416 may be used before striking the substrate 426 supported by the table 422.

For example, an apparatus may include the radiation source 402 of FIG. 4 to generate the radiation beam 404 with an intensity profile and a wavelength capable of heating a region of the substrate 420. A maximum distance of the radiation beam 404 traveled between the radiation source 402 and the region of the substrate 420 may be less than 80 cm. Furthermore, the apparatus an optical element to relay the radiation beam 404 between the radiation source 402 and the substrate 420. The apparatus may also include a projection apparatus (e.g. the projection lens 418 of FIG. 4A) between the DOE 416 and the substrate 420 to focus the radiation beam 404 to the region of the substrate 420. Moreover, the apparatus may include a cooling device coupled to an unused side of the DOE 416 to control a temperature of the DOE 416.

FIG. 4B is a schematic diagrammatic view of a laser scanning device using multiple DOEs and multiple mirrors, according to one embodiment._Particularly, FIG. 4B illustrates a radiation source 452, a radiation beam 454, a mirror 1 456, a mirror 2 458, a mirror 3 460, a mirror 4 462, a telescope 464, a DOE(s) 466, a substrate 468 and a table 470. The radiation source 452 may generate a radiation beam with an intensity profile and a wavelength capable of heating a region of a substrate. The radiation beam 454 may be energy (e.g., a solid state laser, diode laser, a gas laser, and a metal vapor laser) emitted in the form of waves or particles from the radiation source to a substrate at processing stage.

The mirror(s) (e.g., the mirror 1 456, the mirror 2 458, the mirror 3 460, the mirror 462 of FIG. 4B) may be a diffractive, deflective, reflective, and/or transmissive in a variety of shapes (e.g., cone cylinder, concave, convex, etc.) used to change the direction of beam of light as a whole and/or may provide high reflectance and/or durability at individual laser wavelength ranges. The telescope 464 may work by employing one or more curved optical elements lenses or mirrors to gather light or other electromagnetic radiation and/or bring that light or radiation to a focus.

The DOE(s) 466 may be multiple in number (e.g., 5 DOE(s) illustrated in FIG. 4B) and may be a computer generated holographic device that may be used for laser beam shaping and/or sampling. The DOE(s) 466 may be designed to generate a laser intensity distribution that may not be achieved using a conventional lenses and/or mirrors. The substrate 468 may be the base material (e.g., films, foils, textiles, fabrics, plastics, any variety of paper) onto which images may be illuminated. The table 470 may support the substrate 468 to be laser scanned.

In example embodiment in FIG. 4B, the radiation beam 454 generated by the radiation source 452 may change the direction and/or intensity distribution by striking the mirror(s) (e.g., the mirror 1 456, the mirror 2 458, the mirror 3 460, the mirror 462 of FIG. 4B) and/or by passing through the telescope 464. The laser beam may then strike the DOE(S) 416 that may shape and sample the beam before striking the substrate 426 supported by the table 470.

For example, an apparatus may include the radiation source 452 to generate the radiation beam 454 with an intensity profile and a wavelength capable of heating a region of the substrate 468. A maximum distance of the radiation beam 454 traveled between the radiation source 452 and the region of the substrate 468 may be less than 80 cm. The apparatus may further include an optical element to relay the radiation beam 454 between the radiation source 452 and the substrate 468. Moreover, the apparatus may include a cooling device coupled to an unused side of the DOE 466 to control a temperature of the DOE 466.

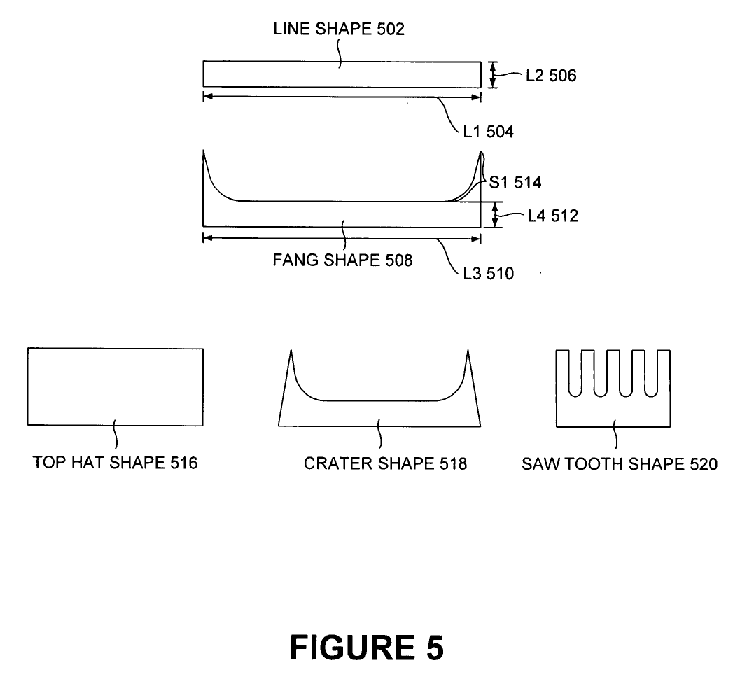

FIG. 5 is image views of various shapes of the radiation beam, according to one embodiment. Particularly, FIG. 5 illustrates various shapes having particular intensity profiles of the radiation beam transformed by the beam shaping device based on the diffractive optical element (DOE), according to one embodiment.

The particular shapes illustrated in the FIG. 5 may be based on the combination of lines formed by the radiation beam with each of the lines to have a particular intensity profile of the particular shape. A line shape 502 may be a particular shape of the radiation beam transformed in the form of a line and/or a rectangle with a particular intensity profile while illuminating region of the substrate. The line shape 502 may be varied through controlling a length 1 (L1) 504 and a length 2 (L2) 506.

In example embodiment illustrated in FIG. 5, the line shape 502 may be a combination of lines formed by the radiation beam 108 of FIG. 1 with each of the lines may have the particular intensity profile. A fang shape 508 may be a particular shape transformed for illuminating region of the substrate and/or may have a higher energy distribution of the radiation beam towards each side of the shape of the radiation beam.

Various forms of the fang shape 508 may be obtained through adjusting a length 3 (L3) 510, a length 4 (L4) 512, and a slope 1 (S1) 514. A top hat shape 516 may be a transformed shape (e.g., resembles the top part of the hat) of the radiation beam 108 of FIG. 1 of particular intensity profile generated through processing the radiation beam 108 of FIG. 1 in a beam shaping device 106 of FIG. 1 based on the diffractive optical element (DOE) 202 of FIG. 2.

A crater shape 518 may be a shape obtained through processing a radiation beam 108 of FIG. 1 in the beam shaping device 106 of FIGS. 1 and 2 based on the diffractive optical element (DOE) 202 of FIG. 1. The saw tooth shape 520 may be a shape of the radiation beam that may be illuminated on the region of the substrate and/or may resemble with the shape of the saw tooth. The top hat shape 506, the crate shape 518 and/or the saw tooth shape 520 may adjust their shapes through controlling parameters such as shown in the line shape 502 and/or the fang shape 508.

For example, an apparatus includes a beam shaping device (e.g., the beam shaping device 106 of FIG. 1) based on a diffractive optical element (DOE) (e.g., DOE 202 of FIG. 2) to transform the radiation beam (e.g., the radiation beam 108 of FIG. 1) to a particular shape (e.g., the particular shape may be based on a combination of lines formed by the radiation beam with each of the lines to have an intensity profile of a fang shape) with a particular intensity profile to illuminate the region. Alternatively, other complex beam shapes and intensity profiles may be devised through customizing the DOE.

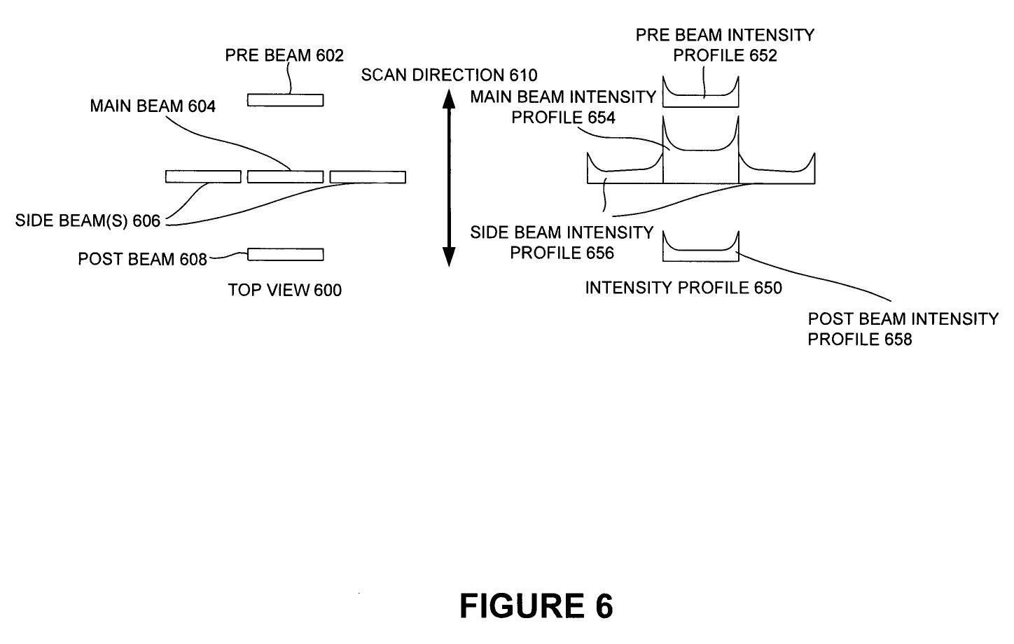

FIG. 6 is a top view and an intensity profile of a combination of lines formed by the radiation beam, according to one embodiment. Particularly, FIG. 6 illustrates a top view 600 and an intensity profile 650, according to one embodiment. The top view 600 of FIG. 6 illustrates different beams continuously illuminating the region of the substrate and may be associated with the radiation beam 108 of FIG. 1 generated from the radiation source. The top view 600 may resemble a cross shape with a main beam 604 surrounded by a pre beam 602, a side beam(s) 606, and a post beam 608.

The intensity profile 650 of FIG. 6 illustrates a pre beam intensity profile 652, a main beam intensity profile 654, a side beam intensity profile 656, and a post beam intensity profile 658 associated with the pre beam 602, the main beam 604, the side beam(s) 606, and post beam 608 of the top view 600 of FIG. 6, according to one embodiment.

The intensity profile 650 may display the main beam intensity profile 654 surrounded by the pre beam intensity profile 652, the side beam intensity profile 656, and the post beam intensity profile 658 in the oriented scan direction 610. The scan direction 610 may be associated with the direction of movement of the laser scanner (e.g., back and forth).

For example, the region of substrate (e.g. the substrate 420 and the substrate 468 of FIGS. 4A and 4B) may be continuously illuminated with the combination of lines. The combination of lines may take a cross shape with the main beam 604 surrounded by the pre beam 602, the two side beams 606, and the post beam 608 with a temperature of the main beam 604 may be 1300° C. and a temperature of the pre beam 602, the two side beams 606, and the post beam 608 may be between 400° C. and 600° C.

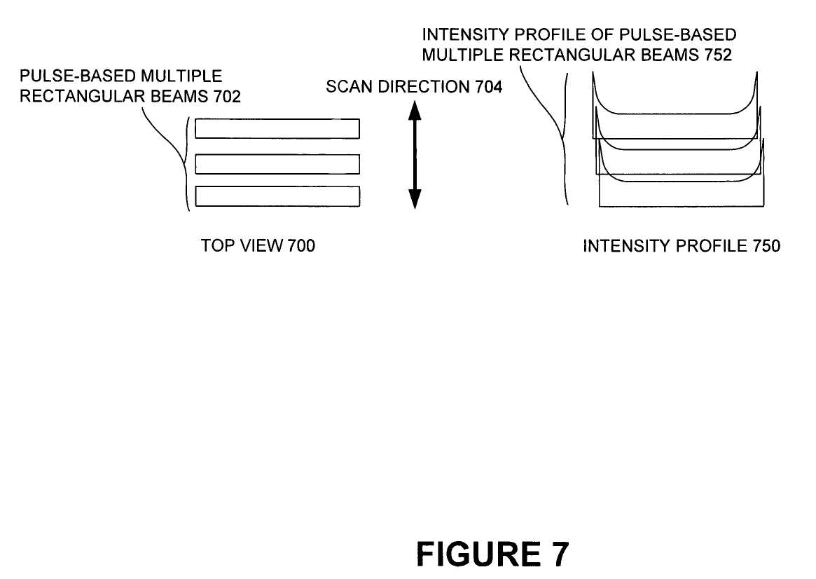

FIG. 7 is a top view and an intensity profile of with a number of parallel lines formed by the radiation source, according to one embodiment. Particularly, FIG. 1 illustrates the top view 700 of pulsed-based multiple rectangular beams 702 and intensity profile 750 of pulse-based multiple rectangular beams, according to one embodiment.

The pulse-based multiple rectangular beams 702 may be parallel lines and may be used for periodically illuminating the region of a substrate. The scan direction 704 as illustrated in example embodiment of FIG. 7 may be the orientation of the laser scanner. The intensity profile 750 may be particular shaped (e.g., fang shaped) intensity profile of pulse-based multiple rectangular beams 752 and may be associated with the pulse-based multiple rectangular beams 702.

For example, the region of the substrate (e.g. the substrate 420 and the substrate 468 of FIGS. 4A and 4B) may be periodically illuminated with a number of parallel lines. The number of parallel lines may be the pulse-based multiple rectangular beams 702 with an intensity profile of each of the pulse-based multiple rectangular beams 702 is a fang-shape.

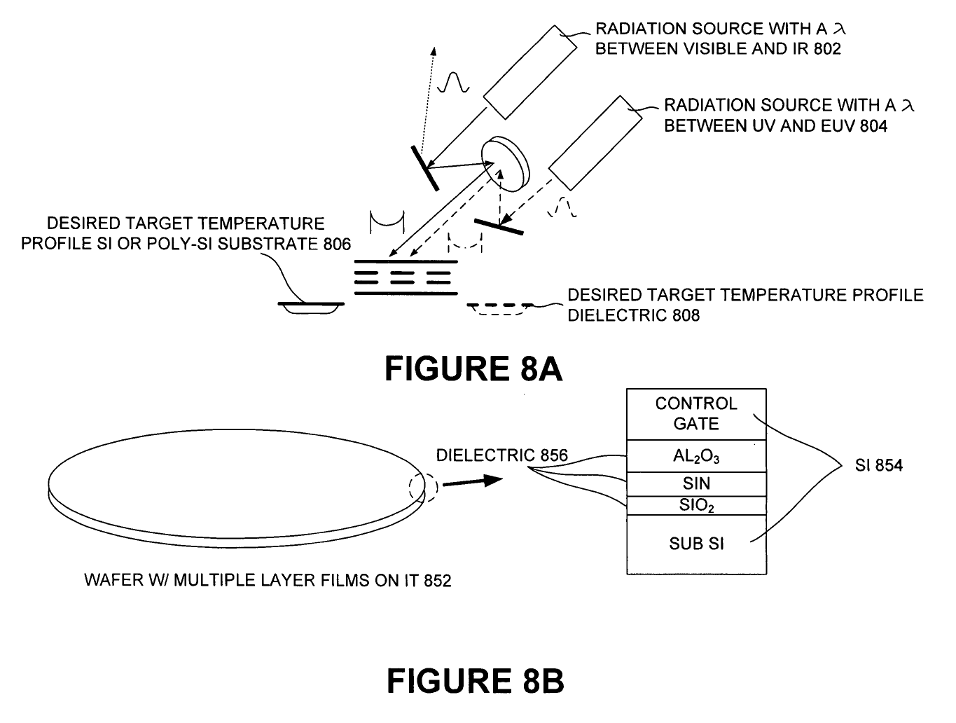

FIG. 8A is a schematic diagram of the laser scanner of FIG. 1 with two laser sources generating two radiation beams having two different wavelengths (λ), according to one embodiment. Particularly, FIG. 8A illustrates a radiation source with a λ (wavelength) between visible and IR 802, a radiation source with a λ (wavelength) between UV and EUV 804, a desired temperature profile Si or poly-Si substrate 806 and/or a desired target temperature profile dielectric 808, according to one embodiment.

The radiation source with a λ (wavelength) between visible and IR 802 may be the laser beam (e.g., CO₂ (10.6 um, IR) and/or diode laser (0.4˜0.9 um, visible)) capable of heating a region of a substrate to one DOE. Similarly, the radiation source with a λ (wavelength) between UV and EUV 804 may be the laser beam (e.g., F₂ (0.157 um, UV)) capable of heating the region of the substrate to that particular DOE. The EUV (Extreme UV) may be characterized by a transition in the physics of interaction with matter.

The radiation emitted may be the Gaussian distribution (e.g., the Gaussian distribution 104 of FIG. 1) that may be a symmetrical frequency distribution having a precise mathematical formula relating the mean and standard deviation of the samples. Moreover, most of the dielectric layers may only absorb thermal energy of UV range while most silicon (Si) may absorb IR and/or visible wavelength range. The desired temperature profile Si or poly-Si substrate 806 may be a desired profile associated with the target temperature of Si and/or poly-Si substrate. The desired target temperature dielectric 808 may be the desired profile of the dielectric that may provide information about the temperature.

In example embodiment illustrated in FIG. 8A, the radiation source with a λ between visible and IR 802 may generate a radiation beam that may get reflected from a mirror and may be incident on the DOE. The radiation source with a λ between UV and EUV 804 may generate a radiation beam that may get reflected from a mirror and may be incident on the DOE. In the example embodiment illustrated in FIG. 8A, the desired target temperature profile Si or poly Si substrate and/or desired target temperature dielectric may be obtained.

For example, an apparatus may include a radiation source to generate a radiation beam with an intensity profile and a wavelength capable of heating a region of a substrate. The apparatus may include an optical element to relay the radiation beam between the radiation source and the substrate.

Furthermore, a first radiation beam (e.g., CO2, diode, etc.) of the multiple radiation beams with its wavelength ranging between a wavelength of a visible light and a wavelength of an infrared light may be generated to illuminate a silicon substrate and/or a poly-silicon substrate, and/or a second radiation beam of the multiple radiation beams with its wavelength ranging between a wavelength of a ultraviolet light and a wavelength of an extreme ultraviolet light may be generated to illuminate dielectric layers.

FIG. 8B is a view of multiple layers of a wafer targeted by the laser scanner of FIG. 8A, according to one embodiment. Particularly, FIG. 8B illustrates a wafer with multiple layer films on it 802, Si 854, and/or dielectric 856, according to one embodiment. The wafer with multiple layer films may consist of five different layers. The multiple layers films may be placed on the surface of the wafer. The wafer may be a thin sheet of semi conducting material, such as a silicon crystal, upon which multiple layers may be constructed by diffusion (or other doping techniques, such as ion implantation) and/or deposition of various materials.

Wafers may be key importance in the fabrication of semiconductor devices. The Si 854 may constitute two silicon layers that may a control gate and/or a sub silicon. The dielectric 856 may be a substance that may be highly resistant to electric current. Moreover, it may include three layers Al₂O₃, SiN and/or SiO₂. In example embodiment illustrated in FIG. 8B, the wafer with multiple layers of films on it 852 may consist of five different layers such as control gate, Al₂O₃, SiN, SiO₂ and/or sub Si. In the example embodiment in FIG. 8B, the layers Al₂O₃, SiN, SiO₂ may be dielectric 856 and the layers control gate and sub Si may be made up of Si 854.

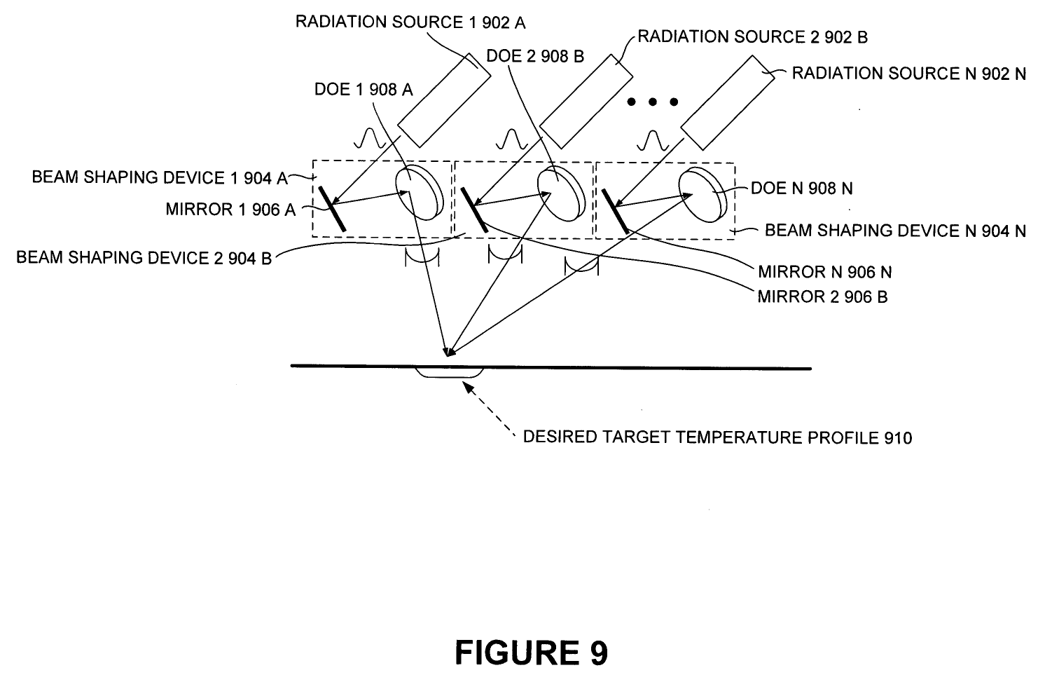

FIG. 9 is a schematic diagram of the laser scanner of FIG. 1 with multiple laser sources generating multiple radiation beams with a unique wavelength, according to one embodiment. Particularly, FIG. 9 illustrates radiation sources 1-N 902 A-N, beam shaping devices 1-N 904 A-N, mirrors 1-N 906 A-N, DOEs 1-N 908 A-N and/or a desired target temperature profile 910, according to one embodiment.

The radiation source 902 may be a laser beam and/or radiation beam with a power between 100 Watts and 3 kWatts that may be operated on a unique wavelength. The beam shaping device 904 may be the device used to shape the laser beam to a particular shape with a particular intensity profile that may be emitted through the DOE 908 from the radiation source 902.

The mirror 906 may reflect the laser beam emitted from the radiation source that may have the original laser profile. The DOE 908 may be a multilayer (e.g., a 16 level, a 64 level, and a 256 level of diffractive layers) device designed to generate a laser intensity distribution emitted from the radiation source through the mirrors that may not be achieved using a conventional lens (e.g., a thin optical lens that may consist of concentric rings used primarily in spotlights, overhead projectors, etc.) and/or mirrors.

The desired target temperature profile 910 may be the desired profile that may be associated with the target temperature. The temperature profile may provide temperature of various laser beams. The radiation source 902 may reflect the laser beam through the mirror, DOE to a common target.

In example embodiment illustrated in FIG. 9, the radiation sources 902 may generate a radiation beam of a particular shape with a particular intensity profile. In the example embodiment illustrated in FIG. 9, the reflection beam may be transformed through the beam shaping devices 904 based on the DOE 908 to obtain the desired target temperature profile 910.

For example, an apparatus may include a radiation source (e.g., the radiation source 1 902A, the radiation source 2 902B, and/or the radiation source 3 902N of FIG. 9), to generate a radiation beam with an intensity profile and a wavelength capable of heating a region of a substrate. The apparatus may further include an optical element (e.g., the DOE 1 908A, the DOE 2 908B, and/or the DOE 3 908N of FIG. 9) to relay the radiation beam between the radiation source and the substrate.

In addition, different layers of the region of the substrate may be illuminated through generating multiple radiation beams (e.g., the multiple radiation beams may have a unique wavelength) using any number of radiation sources (e.g., the radiation source 1 902A, the radiation source 2 902B, and/or the radiation source 3 902N of FIG. 9) and any number of beam shaping devices (e.g., the beam shaping device 1 904A, the beam shaping device 2 904B, and/or the beam shaping device 3 904N of FIG. 9).

FIG. 10 is a schematic diagram of a detector monitoring the radiation beam using a DOE based mirror and/or a mirror with a beam sampler, according to one embodiment. Particularly, FIG. 10 illustrates a radiation source 1002, a (DOE based) mirror, a detector, a radiation source 1052, a mirror 1054, an un-deflected CO₂ laser beam a sampled beam 1058, a detector 1060, according to one embodiment.

The radiation source 1002 may be a solid state laser, diode laser, a gas laser, and a metal vapor laser with one of continuous oscillation and/or pulse oscillation with a power between 100 Watts and 3 kWatts that may be operated on a certain wavelength. The (DOE based) mirror 1004 may receive the radiation beam emitted by the radiation source and/or may reflect to the detector 1006 and/or the DOE. The detector 1006 may be a photo diode, a photo multiplier tube, a pin hole/photo diode, plastic tube, etc. that may be implemented to monitor the laser power stability by directing a small portion of the incoming laser (e.g., blue) from the radiation source 1002.

The detector 1006 may be placed between the radiation source and the DOE and/or the DOE and the target. The radiation source 1052 may be a laser beam and/or radiation beam. The radiation source 1052 may be a solid state laser, diode laser, a gas laser, and a metal vapor laser with one of continuous oscillation and/or pulse oscillation with a power between 100 Watts and 3 kWatts that may be operated on a certain wavelength.

The mirror (with a beam sampler) 1054 may enable the laser beam to reflect/diffract emitted from the radiation source. The mirror may be diffractive, deflective, reflective, and/or transmissive in a variety of shapes (e.g., cone, cylinder, etc.). The un-deflected CO₂ laser beam 1056 may the radiation beam generated by the radiation source 1052 to illuminate the region of the substrate. The sampled beam 1058 may a small portion of the main beam that may be directed towards the detector 1060 to monitor the laser power stability.

For example, an apparatus may include a radiation source (e.g., the radiation source 1002 and the radiation source 1052 of FIG. 10) to generate a radiation beam with an intensity profile and a wavelength capable of heating a region of a substrate. Also, the apparatus may include an optical element to relay the radiation beam between the radiation source (e.g., the radiation source 1002 and the radiation source 1052 of FIG. 10) and the substrate.

Further more, the apparatus may include a beam detector device (e.g., the detector 1006 and the detector 1060 of FIG. 10) to measure the intensity profile and the wavelength of the radiation beam fed into the DOE through capturing a sample of the radiation beam using a DOE based mirror 1004 and/or a mirror with a beam sampler 1054.

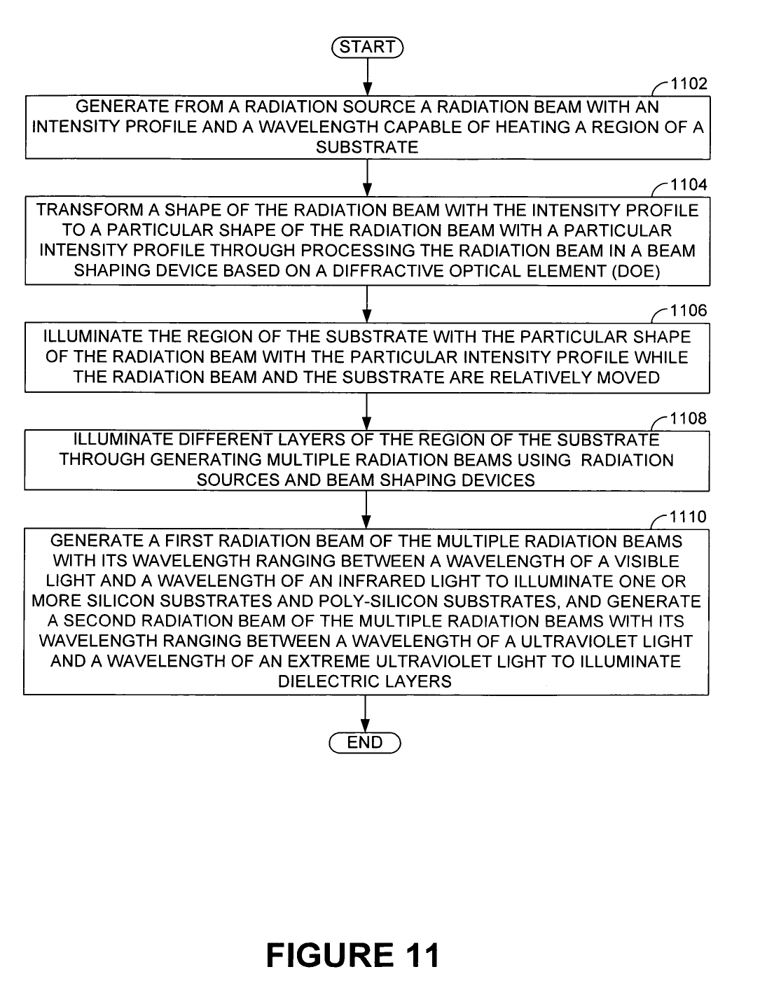

FIG. 11 is the process flow of generating from a radiation source a radiation beam with an intensity profile and a wavelength capable of heating a region of a substrate, according to one embodiment. In operation 1102, a radiation beam (e.g., the radiation beam 108 of FIG. 1) with an intensity profile and a wavelength capable of heating a region of a substrate may be generated from a radiation source (e.g., the radiation source 102 of FIGS. 1 and 2). In operation 1104, a shape of the radiation beam (e.g., the radiation beam 108 of FIG. 1) with the intensity profile may be transformed to a particular shape of the radiation beam (e.g., the radiation beam 108 of FIG. 1) with a particular intensity profile through processing the radiation beam (e.g., the radiation beam 108 of FIG. 1) in a beam shaping device (e.g., the beam shaping device 106 of FIG. 1) based on a diffractive optical element (DOE) (e.g., DOE 202 of FIG. 2).

In operation 1106, the region of the substrate with the particular shape of the radiation beam (e.g., the radiation beam 108 of FIG. 1) with the particular intensity profile may be illuminated while the radiation beam (e.g., the radiation beam 108 of FIG. 1) and the substrate are relatively moved. In operation 1108, different layers of the region of the substrate may be illuminated through generating multiple radiation beams using radiation sources (e.g., the radiation source 102 of FIGS. 1 and 2) and beam shaping devices (e.g., the beam shaping device 106 of FIG. 1).

In operation 1110, a first radiation beam of the multiple radiation beams may be generated with its wavelength ranging between a wavelength of a visible light and a wavelength of an infrared light to illuminate one or more silicon substrates and poly-silicon substrates, and a second radiation beam of the multiple radiation beams may be generated with its wavelength ranging between a wavelength of a ultraviolet light and a wavelength of an extreme ultraviolet light to illuminate dielectric layers.

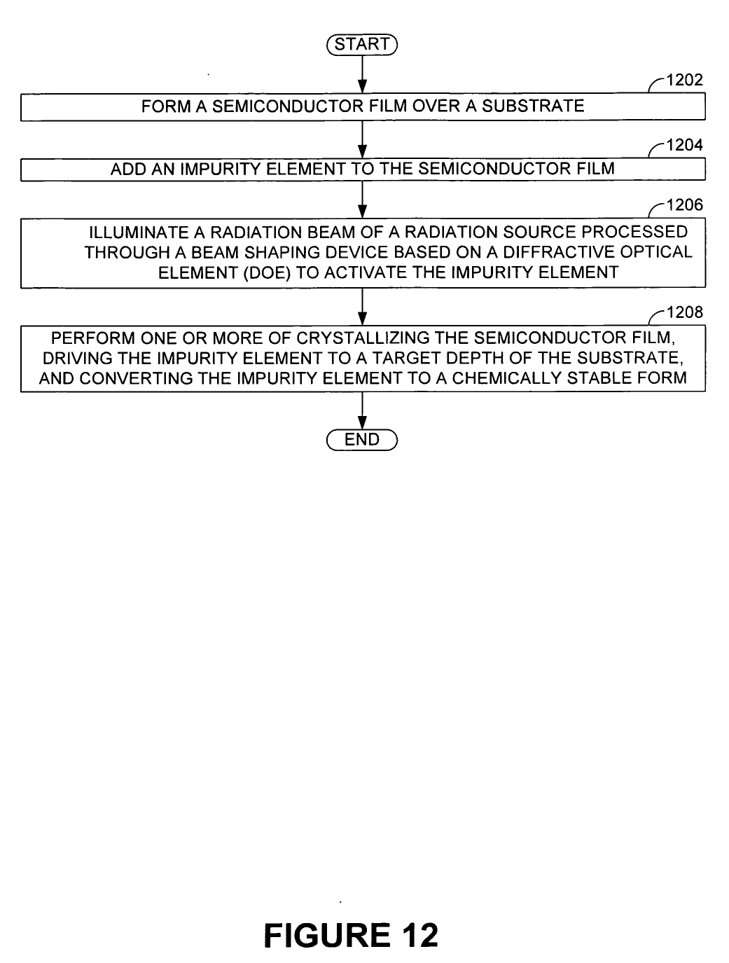

FIG. 12 is a process flow of forming a semiconductor over a substrate, according to on embodiment. In operation 1202, a semiconductor film may be formed over a substrate. In operation 1204, an impurity element may be added to the semiconductor film. In operation 1206, a radiation beam (e.g., the radiation beam 108 of FIG. 1) of a radiation source (e.g., the radiation source 102 of FIGS. 1 and 2) processed may be illuminated through a beam shaping device (e.g., the beam shaping device 106 of FIG. 1) based on a diffractive optical element (DOE) (e.g., the DOE 202 of FIG. 2) to activate the impurity element. In operation 1208, one or more of crystallizing the semiconductor film, driving the impurity element to a target depth of the substrate, and converting the impurity element to a chemically stable form may be performed.

Also, the method may be in a form of a machine-readable medium embodying a set of instructions that, when executed by a machine, cause the machine to perform any method disclosed herein. It will be appreciated that the various embodiments discussed herein may/may not be the same embodiment, and may be grouped into various other embodiments not explicitly disclosed herein.

In addition, it will be appreciated that the various operations, processes, and methods disclosed herein may be embodied in a machine-readable medium and/or a machine accessible medium compatible with a data processing system (e.g., a computer system), and may be performed in any order (e.g., including using means for achieving the various operations). Accordingly, the specification and drawings are to be regarded in an illustrative rather than a restrictive sense.

What is claimed is:

1. An apparatus, comprising:
a radiation source to generate a radiation beam with an intensity profile and a wavelength capable of heating a region of a substrate;
a beam shaping device based on a diffractive optical element (DOE) to transform the radiation beam to a particular shape with a particular intensity profile to illuminate the region; and
a stage adapted to support the substrate,
wherein the beam shaping device and the stage are relatively moved to illuminate the particular shape with the particular intensity profile of the radiation beam to the region.

2. The apparatus of claim 1, wherein the radiation source is at least one of a solid state laser, a diode laser, a gas laser, and a metal vapor laser of at least one of continuous oscillation and pulse oscillation with a power between 100 Watts and 3 kWatts.

3. The apparatus of claim 2, wherein the wavelength is at least one of 10.6 um for a CO₂ laser, 0.4 um˜0.9 um for the diode laser, and 0.157 um for a F₂ laser.

4. The apparatus of claim 3, wherein the DOE is at least one of a reflective DOE and a transmissive DOE.

5. The apparatus of claim 4, wherein the DOE is a multilayer diffractive optical element (DOE) which includes at least a 16 level, a 64 level, and a 256 level of diffractive layers.

6. The apparatus of claim 5, wherein a maximum distance of the radiation beam traveled between the radiation source and the region of the substrate is less than 80 cm.

7. The apparatus of claim 6, wherein the particular shape is at least one of a line and a rectangle and wherein the particular intensity profile is a fang shape which has a higher energy distribution of the radiation beam towards each side of the particular shape.

8. The apparatus of claim 7, further comprising a reflectivity measurement device to measure the intensity profile of the radiation beam illuminating the region through sampling the radiation beam reflected from the region.

9. The apparatus of claim 8, further comprising at least one optical element to relay the radiation beam between the radiation source and the substrate.

10. The apparatus of claim 9, further comprising a projection apparatus between the DOE and the substrate to focus the radiation beam to the region of the substrate.

11. The apparatus of claim 10, further comprising a beam detector device to measure at least one of the intensity profile and the wavelength of the radiation beam fed into the DOE through capturing a sample of the radiation beam using at least one of a DOE based mirror and a mirror with a beam sampler.

12. The apparatus of claim 11, further comprising a cooling device coupled to an unused side of the DOE to control a temperature of the DOE.

13. A method, comprising:
generating from a radiation source a radiation beam with an intensity profile and a wavelength capable of heating a region of a substrate;
transforming a shape of the radiation beam with the intensity profile to a particular shape of the radiation beam with a particular intensity profile through processing the radiation beam in a beam shaping device based on a diffractive optical element (DOE); and
illuminating the region of the substrate with the particular shape of the radiation beam with the particular intensity profile while the radiation beam and the substrate are relatively moved.

14. The method of claim 13, further comprising illuminating different layers of the region of the substrate through generating multiple radiation beams using a plurality of radiation sources and a plurality of beam shaping devices, wherein each of the multiple radiation beams to have a unique wavelength.

15. The method of claim 14, further comprising generating a first radiation beam of the multiple radiation beams with its wavelength ranging between a wavelength of a visible light and a wavelength of an infrared light to illuminate at least one of a silicon substrate and a poly-silicon substrate, and generating a second radiation beam of the multiple radiation beams with its wavelength ranging between a wavelength of a ultraviolet light and a wavelength of an extreme ultraviolet light to illuminate dielectric layers.

16. The method of claim 15, wherein the particular shape is based on a combination of lines formed by the radiation beam with each of the lines to have an intensity profile of a fang shape.

17. The method of claim 16, further comprising continuously illuminating the region of substrate with the combination of lines, wherein the combination of lines to take a cross shape with a main beam surrounded by a pre beam, two side beams, and a post beam with a temperature of the main beam is at least 1300° C. and a temperature of the pre beam, the two side beams, and the post beam is between 400° C. and 600° C.

18. The method of claim 17, further comprising periodically illuminating the region of the substrate with a number of parallel lines, wherein the number of parallel lines are pulse-based multiple rectangular beams with the intensity profile of each of the pulse-based multiple rectangular beams is the fang-shape.

19. The method of claim 18 in a form of a machine-readable medium embodying a set of instructions that, when executed by a machine, causes the machine to perform the method of claim 18.

20. A method, comprising:
forming a semiconductor film over a substrate;
adding an impurity element to the semiconductor film;
illuminating a radiation beam of a radiation source processed through a beam shaping device based on a diffractive optical element (DOE) to activate the impurity element; and
performing at least one of crystallizing the semiconductor film, driving the impurity element to a target depth of the substrate, and converting the impurity element to a chemically stable form.

21. A method, comprising:
forming at least one dielectric film to a substrate; and
illuminating a radiation beam of a radiation source processed through a beam shaping device based on a diffractive optical element (DOE) to apply a stress to the at least one dielectric film.
